(19) United States
(12) Patent Application Publication
(10) Pub. No.: US 2010/0316949 A1
(43) Pub. Date: Dec. 16, 2010

(54) Spin On Organic Antireflective Coating Composition Comprising Polymer with Fused Aromatic Rings

(76) Inventors: M. Dalil Rahman, Flemington, NJ (US); Douglas McKenzie, Easton, PA (US); Guanyang Lin, Whitehouse Station, NJ (US); Jianhui Shan, Pennington, NJ (US); Ruzhi Zhang, Pennington, NJ (US); Mark Neisser, Whitehouse Station, NJ (US)

Correspondence Address: SANGYA JAIN;AZ ELECTRONIC MATERIALS USA CORP., 70 MEISTER AVENUE, SOMERVILLE, NJ, 08876, US

(21) Appl. No.: 12/482,189

(22) Filed: Jun. 10, 2009

(51) Int. Cl. G03F 7/20; C08G 65/38; G03F 7/004; B29C 59/02

(52) U.S. Cl. 430/270.1; 528/212; 430/311; 264/293

(57) ABSTRACT

The present invention relates to an organic spin on hard mask antireflective coating composition comprising a polymer comprising at least one unit of fused aromatic rings in the backbone of the polymer and at least one unit with a cycloaliphatic moiety in the backbone of the polymer. The invention further relates to a process for making the polymer and a process for imaging the present composition.

### FIELD OF INVENTION

The present invention relates to an absorbing antireflective coating composition comprising a polymer with at least one aliphatic unit and at least one unit with substituted or unsubstituted aromatic fused rings, a process of making the polymer and a process for forming an image using the antireflective coating composition. The process is especially useful for imaging photoresists using radiation in the deep and extreme ultraviolet (uv) region.

### BACKGROUND OF INVENTION

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon based wafers used for making integrated circuits. The coated substrate is then baked to evaporate any solvent in the photoresist composition and to fix the coating onto the substrate. The baked coated surface of the substrate is next subjected to an image-wise exposure to radiation.

The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

The trend towards the miniaturization of semiconductor devices has led to the use of new photoresists that are sensitive to lower and lower wavelengths of radiation and has also led to the use of sophisticated multilevel systems to overcome difficulties associated with such miniaturization.

Absorbing antireflective coatings and underlayers in photolithography are used to diminish problems that result from back reflection of light from highly reflective substrates. Two major disadvantages of back reflectivity are thin film interference effects and reflective notching. Thin film interference, or standing waves, result in changes in critical line width dimensions caused by variations in the total light intensity in the photoresist film as the thickness of the photoresist changes or interference of reflected and incident exposure radiation can cause standing wave effects that distort the uniformity of the radiation through the thickness. Reflective notching becomes severe as the photoresist is patterned over reflective substrates containing topographical features, which scatter light through the photoresist film, leading to line width variations, and in the extreme case, forming regions with complete photoresist loss. An antireflective coating coated beneath a photoresist and above a reflective substrate provides significant improvement in lithographic performance of the photoresist. Typically, the bottom antireflective coating is applied on the substrate and then a layer of photoresist is applied on top of the antireflective coating. The antireflective coating is cured to prevent intermixing between the antireflective coating and the photoresist. The photoresist is exposed imagewise and developed. The antireflective coating in the exposed area is then typically dry etched using various etching gases, and the photoresist pattern is thus transferred to the substrate. Multiple antireflective layers and underlayers are being used in new lithographic techniques. In cases where the photoresist does not provide sufficient dry etch resistance, underlayers or antireflective coatings for the photoresist that act as a hard mask and are highly etch resistant during substrate etching are preferred, and one approach has been to incorporate silicon into a layer beneath the organic photoresist layer. Additionally, another high carbon content antireflective or mask layer is added beneath the silicon antireflective layer, which is used to improve the lithographic performance of the imaging process. The silicon layer may be spin coatable or deposited by chemical vapor deposition. Silicon is highly etch resistant in processes where O₂ etching is used, and by providing a organic mask layer with high carbon content beneath the silicon antireflective layer, a very large aspect ratio can be obtained. Thus, the organic, high carbon mask layer can be much thicker than the photoresist or silicon layer above it The organic mask layer can be used as a thicker film and can provide better substrate etch masking that the original photoresist.

The present invention relates to a novel organic spin coatable antireflective coating composition or organic mask underlayer which has high carbon content, and can be used between a photoresist layer and the substrate as a single layer of one of multiple layers. Typically, the novel composition can be used to form a layer beneath an essentially etch resistant antireflective coating layer, such as a silicon antireflective coating. The high carbon content in the novel antireflective coating, also known as a carbon hard mask underlayer, allows for a high resolution image transfer with high aspect ratio. The higher the carbon content of the underlayer the better the etch resistance. Thus underlayers with high carbon content are desirable. The novel composition is useful for imaging photoresists, and also for etching the substrate. The novel composition enables a good image transfer from the photoresist to the substrate, and also reduces reflections and enhances pattern transfer. Additionally, substantially no intermixing is present between the antireflective coating and the film coated above it. The antireflective coating also has good solution stability and forms films with good coating quality, the latter being particularly advantageous for lithography.

### SUMMARY OF THE INVENTION

The present invention relates to an organic spin coatable antireflective coating composition comprising a polymer comprising at least one unit of fused aromatic rings in the backbone of the polymer and at least one unit with a cycloaliphatic moiety in the backbone of the polymer. The invention further relates to a process for imaging the present composition. The invention also relates to a process for making the polymer.

### BRIEF DESCRIPTION OF DRAWINGS

FIG. 1 shows examples of aliphatic monomers.

FIG. 2 shows an example of the polymeric unit.

FIG. 3 illustrates the process of imaging.

### DESCRIPTION OF THE INVENTION

The present invention relates to an absorbing antireflective coating composition comprising a crosslinkable polymer with at least one cycloaliphatic unit in the backbone of the polymer and at least one fused aromatic unit in the backbone of the polymer, a process for making the polymer and a process for forming an image using the antireflective coating composition. The invention also relates to a process for imaging a photoresist layer coated above the novel antireflective coating layer.

The novel antireflective coating of the present invention comprises a novel copolymer and mixture of co polymers with high carbon content which is capable of crosslinking, such that the coating becomes insoluble in the solvent of the material coated above it. The novel coating composition is capable of self-crosslinking or may additionally comprise a crosslinking compound capable of crosslinking with the polymer. In one embodiment the novel composition comprises the polymer, a crosslinking compound and a thermal acid generator. The novel composition may additionally comprise other additives, such as organic acids, esters, thermal acid generators, photoacid generators, surfactants, other high carbon content polymers etc. The solid components of the novel composition are dissolved in an organic coating solvent composition, comprising one or more organic solvents. The novel polymer is soluble in the organic coating solvent(s).

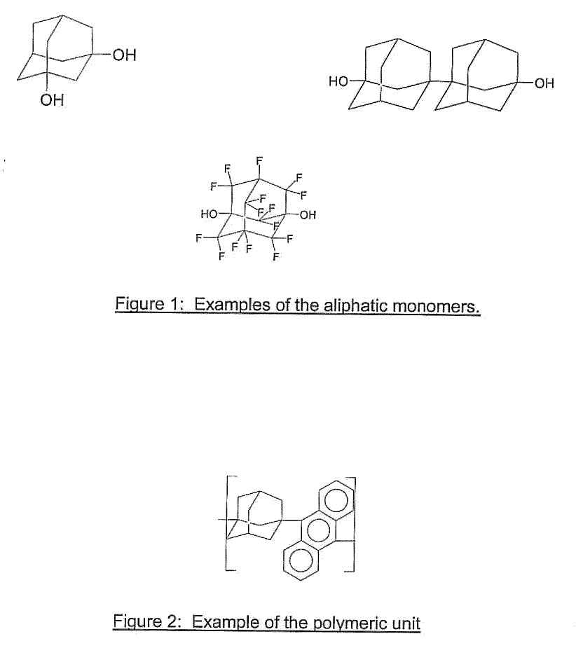

The polymer of the novel composition comprises at least one unit of fused aromatic moiety and at least one unit of an cycloaliphatic moiety in the backbone of the polymer. The novel polymer is obtained by a condensation reaction of a monomer comprising a fused aromatic moiety and a monomer comprising a cycloaliphatic unit with hydroxyl, amino or alkoxy groups, in presence of acid catalyst. Examples of possible monomers are given in FIG. 1. The aromatic moiety is fused aromatic rings, which are substituted or unsubstituted, and provide the absorption for the coating, and are the absorbing chromophore. The fused aromatic rings of the polymer can comprise 2 to 10 membered aromatic rings. Examples of the fused aromatic moiety are the following structures 1-7,

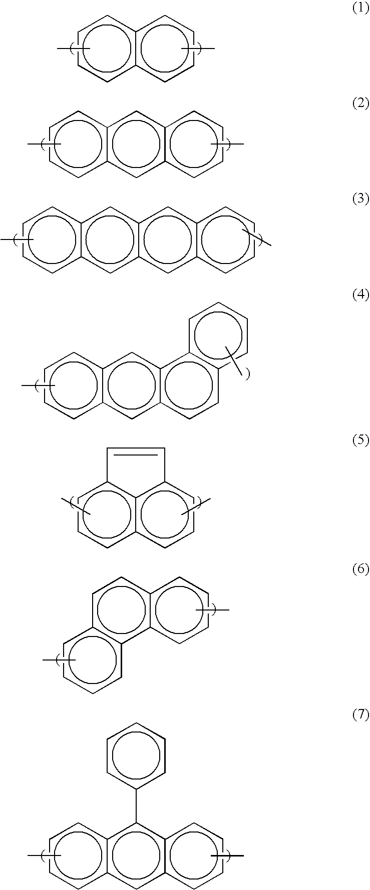

Although, in addition to as shown in structures 1-7, the fused rings may form the backbone of the polymer at any site in the aromatic structure and the attachment sites may vary within the polymer. The fused ring structure can have more than 2 points of attachment forming a branched oligomer or branched polymer.

In one embodiment of the polymer, the fused aromatic unit is connected to an aliphatic carbon moiety or another fused aromatic unit. Blocks of fused aromatic units or a single aromatic unit may be separated by the aliphatic unit.

The fused aromatic rings of the polymer may be unsubstituted or substituted with one or more organo constituents, such as alkyl, substituted alkyl, aryl, substituted aryl, alkylaryl, and haloalkyls; preferably hydroxyl methyl, aminomethyl, bromomethyl, and chloromethyl group. The substituents on the aromatic rings may aid in the solubility of the polymer in the coating solvent. Some of the substituents on the fused aromatic structure may also be thermolysed during curing, such that they may not remain in the cured coating and may still give a high carbon content film useful during the etching process. The fused aromatic rings of the polymer can comprise 2 to 10 aromatic rings with substituents, as shown in the following structures 8-14,

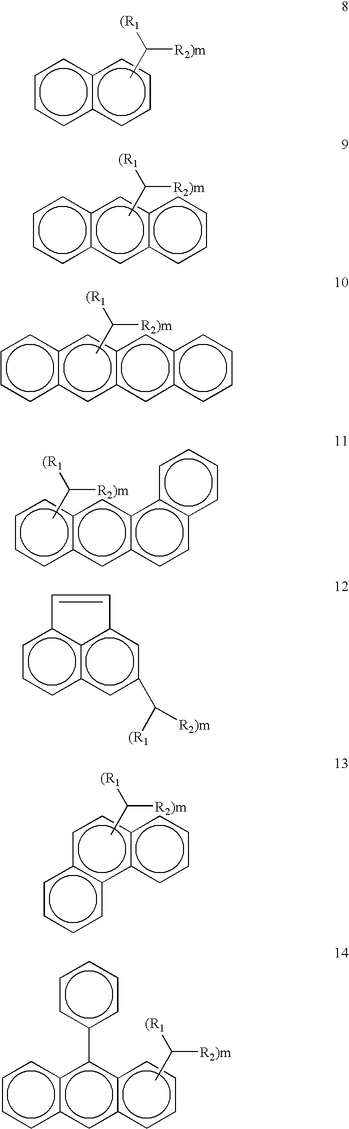

Where, R₁═H, C₁ to C₁₀ alkyl or aryl; R₂═OH, NH₂, alkoxy, and m is one to four.

The polymer may comprise more than one type of the fused aromatic structures described herein.

In addition to the aromatic unit, the polymer of the novel antireflective coating further comprises at least one unit with an essentially cyclic aliphatic moiety in the backbone of the polymer, and the moiety is any that has a nonaromatic structure that forms the backbone of the polymer, such as an alkylene which is primarily a carbon/hydrogen nonaromatic moiety. The polymer can comprise at least one unit which forms only an aliphatic backbone in the polymer. The polymer may comprise units, -(A)- and —(B)—, where A is any fused aromatic unit described previously, which may be linear or branched, and where B has only an cyclic aliphatic backbone. B may further have pendant substituted or unsubstituted aryl or aralkyl groups or be connected to form a branched polymer. Multiple types of the alkylene units may be in the polymer. More specific groups of the aliphatic comonomeric unit are exemplified by adamantylene, dicyclopentylene, and hydroxy adamantylene. The most preferable of unit B are adamantanylene and perfluoroadamantylene. Monomers such as 1,3-hydroxyadamantane and perfluoro 1,3-hydroxyadamantane may be used to form the cyclic aliphatic unit.

Aryl groups contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g. alkyl, alkoxy, acyl or aryl groups mentioned hereinabove. Similarly, appropriate polyvalent aryl groups as desired may be used in this invention. Representative examples of divalent aryl groups include phenylenes, xylylenes, naphthylenes, biphenylenes, and the like. Alkoxy means straight or branched chain alkoxy having 1 to 20 carbon atoms, and includes, for example, methoxy, ethoxy, n-propoxy, isopropoxy, n-butoxy, isobutoxy, tert-butoxy, pentyloxy, hexyloxy, heptyloxy, octyloxy, nonanyloxy, decanyloxy, 4-methylhexyloxy, 2-propylheptyloxy, and 2-ethyloctyloxy. Aralkyl means aryl groups with attached substituents. The substituents may be any such as alkyl, alkoxy, acyl, etc. Examples of monovalent aralkyl having 7 to 24 carbon atoms include phenylmethyl, phenylethyl, diphenylmethyl, 1,1- or 1,2-diphenylethyl, 1,1-, 1,2-, 2,2-, or 1,3-diphenylpropyl, and the like. Appropriate combinations of substituted aralkyl groups as described herein having desirable valence may be used as a polyvalent aralkyl group.

The polymer of the present novel composition may be synthesized by reacting a) at least one aromatic compound comprising 2 or more fused aromatic rings capable of electrophilic substitution such that the fused rings form the backbone of the polymer, with b) at least one essentially cyclic aliphatic compound. The aromatic compound may be selected from monomers that provide the desired aromatic unit, more specifically structures shown above or equivalents, and may be further selected from compounds such as anthracene, phenanthrene, pyrene, fluoranthene, and coronene triphenylene. The fused aromatic ring monomers provide at least 2 reactive hydrogens, which are sites for electrophilic substitution. The aliphatic compound is an essentially cyclic substituted or unsubstituted aliphatic alkyl compound capable of forming the aliphatic unit in the polymer, and also capable of forming a carbocation in the presence of an acid, and may be selected from compounds such as aliphatic diol, aliphatic triol, aliphatic tetrol, aliphatic alkene, aliphatic diene, aliphatic diamine, aliphatic triamine, aliphatic tetramine, aliphatic dialkoxy, aliphatic trialkoxy, aliphatic tetra-alkoxy etc. Any compound that is capable of forming the alkylene unit in the polymer of the novel composition as described previously may be used. The aliphatic monomer may be exemplified by 1,3-adamantanediol, 1,5-adamantanediol, 1,3,5-adamantanetriol, 1,3,5-cyclohexanetriol, perfluoro 1,3-adamantane diol and dicyclopentadiene. The reaction is catalysed in the presence of a strong acid, such as a sulfonic acid. Any sulfonic acid may be used, examples of which are triflic acid, nonafluorobutane sulfonic acid, bisperfluoroalkylimides, trisperfluoroalkylcarbides, or other strong nonnucleophilic acids. The reaction may be carried out with or without a solvent. If a solvent is used then any solvent capable of dissolving the solid components may be used, especially one which is nonreactive towards strong acids; solvents such as chloroform, bis(2-methoxyethyl ether), nitrobenzene, methylene chloride, and diglyme may be used. The reaction may be mixed for a suitable length of time at a suitable temperature, till the polymer is formed. The reaction time may range from about 3 hours to about 24 hours, and the reaction temperature may range from about 80° C. to about 180° C. The polymer is isolated and purified in appropriate solvents, such as methanol, hexane or heptane through precipitation and washing. Previously known techniques of reacting, isolating and purifying the polymer may be used. The weight average molecular weight of the polymer can range from about 1000 to about 50,000, or about 1300 to about 20,000. The refractive indices of the polymer, n (refractive index) and k (absorption) can range from about 1.3 to about 2.0 for the refractive index and about 0.05 to about 1.0 for the absorption at the exposure wavelength used, such as 193 nm. The carbon content of the polymer is greater than 80% as measured by elemental analysis, preferably greater than 85%, even more preferably greater than 88%.

The polymer of the present novel composition may have the structural unit as shown in FIG. 2.

The novel composition of the present invention comprises the polymer and may further comprise a crosslinker and/or a thermal acid generator. Typically the crosslinker is a compound that can act as an electrophile and can, alone or in the presence of an acid, form a carbocation. Thus compounds containing groups such as alcohol, ether, ester, olefin, methoxymethylamino, methoxymethylphenyl and other molecules containing multiple electrophilic sites, are capable of crosslinking with the polymer. Examples of compounds which can be crosslinkers are, 1,3 adamantane diol, 1,3,5 adamantane trio, polyfunctional reactive benzylic compounds, tetramethoxymethyl-bisphenol (TMOM-BP) of structure (15), aminoplast crosslinkers, glycolurils, Cymels, Powderlinks, etc.

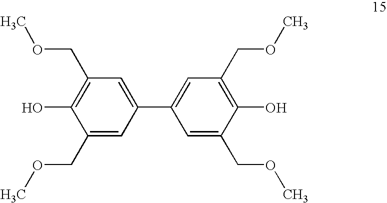

The novel composition comprising the polymer may also comprise an acid generator, and optionally the crosslinker. The acid generator can be a thermal acid generator capable of generating a strong acid upon heating. The thermal acid generator (TAG) used in the present invention may be any one or more that upon heating generates an acid which can react with the polymer and propagate crosslinking of the polymer present in the invention, particularly preferred is a strong acid such as a sulfonic acid. Preferably, the thermal acid generator is activated at above 90° C. and more preferably at above 120° C., and even more preferably at above 150° C. Examples of thermal acid generators are metal-free sulfonium salts and iodonium salts, such as triarylsulfonium, alkylarylsulfonium, and diarylalkylsulfonium salts of strong non-nucleophilic acids, alkylaryliodonium, diaryliodonium salts of strong non-nucleophilic acids; and ammonium, alkylammonium, dialkylammonium, trialkylammonium, tetraalkylammonium salts of strong non nucleophilic acids. Also, covalent thermal acid generators are also envisaged as useful additives for instance 2-nitrobenzyl esters of alkyl or arylsulfonic acids and other esters of sulfonic acid which thermally decompose to give free sulfonic acids. Examples are diaryliodonium perfluoroalkylsulfonates, diaryliodonium tris(fluoroalkylsulfonyl)methide, diaryliodonium bis(fluoroalkylsulfonyl)methide, diarlyliodonium bis(fluoroalkylsulfonyl)imide, diaryliodonium quaternary ammonium perfluoroalkylsulfonate. Examples of labile esters: 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; quaternary ammonium tris(fluoroalkylsulfonyl)methide, and quaternaryalkyl ammonium bis(fluoroalkylsulfonyl)imide, alkyl ammonium salts of organic acids, such as triethylammonium salt of 10-camphorsulfonic acid. A variety of aromatic (anthracene, naphthalene or benzene derivatives) sulfonic acid amine salts can be employed as the TAG, including those disclosed in U.S. Pat. Nos. 3,474,054, 4,200,729, 4,251,665 and 5,187,019. Preferably the TAG will have a very low volatility at temperatures between 170-220° C. Examples of TAGs are those sold by King Industries under Nacure and CDX names. Such TAG's are Nacure 5225, and CDX-2168E, which is a dodecylbenzene sulfonic acid amine salt supplied at 25-30% activity in propylene glycol methyl ether from King Industries, Norwalk, Conn. 06852, USA.

The novel composition may further contain at least one of the known photoacid generators, examples of which without limitation, are onium salts, sulfonate compounds, nitrobenzyl esters, triazines, etc. The preferred photoacid generators are onium salts and sulfonate esters of hydoxyimides, specifically diphenyl iodonium salts, triphenyl sulfonium salts, dialkyl iodonium salts, triakylsulfonium salts, and mixtures thereof. These photoacid generators are not necessarily photolysed but are thermally decomposed to form an acid.

The antireflective coating composition of the present invention may contain 1 weight % to about 30 weight % of the fused aromatic polymer, and preferably 4 weight % to about 15 weight %, of total solids. The crosslinker, when used in the composition, may be present at about 1 weight % to about 30 weight % of total solids. The acid generator, may be incorporated in a range from about 0.1 to about 10 weight % by total solids of the antireflective coating composition, preferably from 0.3 to 5 weight % by solids, and more preferably 0.5 to 2.5 weight % by solids.

The solid components of the antireflection coating composition are mixed with a solvent or mixtures of solvents that dissolve the solid components of the antireflective coating. Suitable solvents for the antireflective coating composition may include, for example, a glycol ether derivative such, as ethyl cellosolve, methyl cellosolve, propylene glycol monomethyl ether (PGME), diethyene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA); carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether, a ketone alcohol derivative such as acetol or diacetone alcohol; lactones such as butyrolactone; an amide derivative such as dimethylacetamide or dimethylformamide, anisole, and mixtures thereof.

The antireflective coating composition comprises the polymer, and other components may be added to enhance the performance of the coating, e.g. monomeric dyes, lower alcohols (C₁-C₆ alcohols), surface leveling agents, adhesion promoters, antifoaming agents, etc.

Since the antireflective film is coated on top of the substrate and is also subjected to dry etching, it is envisioned that the film is of sufficiently low metal ion level and of sufficient purity that the properties of the semiconductor device are not adversely affected. Treatments such as passing a solution of the polymer through an ion exchange column, filtration, and extraction processes can be used to reduce the concentration of metal ions and to reduce particles.

The absorption parameter (k) of the novel composition ranges from about 0.05 to about 1.0, preferably from about 0.1 to about 0.8 at the exposure wavelength, as derived from ellipsometric measurements. In one embodiment the composition has a k value in the range of about 0.2 to about 0.5 at the exposure wavelength. The refractive index (n) of the antireflective coating is also optimized and can range from about 1.3 to about 2.0, preferably 1.5 to about 1.8. The n and k values can be calculated using an ellipsometer, such as the J. A. Woollam WVASE VU-32™ Ellipsometer. The exact values of the optimum ranges for k and n are dependent on the exposure wavelength used and the type of application. Typically for 193 nm the preferred range for k is about 0.05 to about 0.75, and for 248 nm the preferred range for k is about 0.15 to about 0.8.

The carbon content of the novel antireflective coating composition is greater than 80 weight % or greater than 85 weight % or greater than 88% as measured by elemental analysis.

The antireflective coating composition is coated on the substrate using techniques well known to those skilled in the art, such as dipping, spin coating or spraying. The film thickness of the antireflective coating ranges from about 15 nm to about 400 nm. The coating is further heated on a hot plate or convection oven for a sufficient length of time to remove any residual solvent and induce crosslinking, and thus insolubilizing the antireflective coating to prevent intermixing between the antireflective coating and the layer to be coated above it. The preferred range of temperature is from about 90° C. to about 280° C.

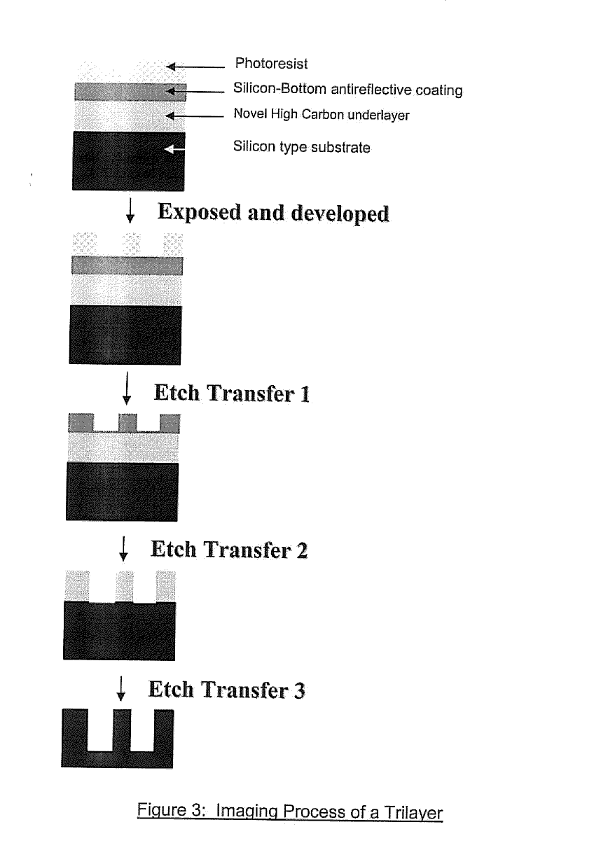

Other types of antireflective coatings may be coated above the coating of the present invention. Typically, an antireflective coating which has a high resistance to oxygen etching, such as one comprising silicon groups, such as siloxane, functionalized siloxanes, silsesquioxanes, or other moieties that reduce the rate of etching, etc., is used so that the coating can act as a hard mask for pattern transference. The silicon coating can be spin coatable or chemical vapor deposited. In one embodiment the substrate is coated with a first film of the novel composition of the present invention and a second coating of another antireflective coating comprising silicon is coated above the first film. The second coating can have an absorption (k) value in the range of about 0.05 and 0.5. A film of photoresist is then coated over the second coating. The imaging process is exemplified in FIG. 3.

A film of photoresist is coated on top of the uppermost antireflective coating and baked to substantially remove the photoresist solvent. An edge bead remover may be applied after the coating steps to clean the edges of the substrate using processes well known in the art.

The substrates over which the antireflective coatings are formed can be any of those typically used in the semiconductor industry. Suitable substrates include, without limitation, low dielectric constant materials, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds. The substrate may comprise any number of layers made from the materials described above.

Photoresists can be any of the types used in the semiconductor industry, provided the photoactive compound in the photoresist and the antireflective coating substantially absorb at the exposure wavelength used for the imaging process.

To date, there are several major deep ultraviolet (uv) exposure technologies that have provided significant advancement in miniaturization, and these radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure at 193 nm and 157 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference. Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art. The novel coatings can also be used in nanoimprinting and e-beam lithography.

After the coating process, the photoresist is imagewise exposed. The exposure may be done using typical exposure equipment. The exposed photoresist is then developed in an aqueous developer to remove the treated photoresist. The developer is preferably an aqueous alkaline solution comprising, for example, tetramethyl ammonium hydroxide (TMAH). The developer may further comprise surfactant(s). An optional heating step can be incorporated into the process prior to development and after exposure.

The process of coating and imaging photoresists is well known to those skilled in the art and is optimized for the specific type of photoresist used. The patterned substrate can then be dry etched with an etching gas or mixture of gases, in a suitable etch chamber to remove the exposed portions of the antireflective film or multiple layers of antireflective coatings, with the remaining photoresist acting as an etch mask. Various etching gases are known in the art for etching organic antireflective coatings, such as those comprising O₂, CF₄, CHF₃, Cl₂, HBr, SO₂, CO, etc.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

The refractive index (n) and the absorption (k) values of the carbon hard mask antireflective coating in the Examples below were measured on a J. A. Woollam VASE32 ellipsometer.

The molecular weight of the polymers was measured on a Gel Permeation Chromatograph.

### Example 1

### Synthesis of Copolymer of 1,3-Adamantane diol and 9-anthracenemethanol

1,3-Adamantane diol (8.4 g, 0.05 mole) and 9-anthracenemethanol (22.9 g, 0.11 mole) and solvents cyclopentylmethylether (CPME) 23 g and diethyleneglycolmethylether (DEGME) 81 g were taken in a 500 mL, 4 neck, round bottomed flask equipped with overhead mechanical stirring₁ condenser, thermo watch, dean stark trap, and N₂ purge. The components were mixed together at room temperature for 10 minutes and 1.0 g of triflic acid was added. It was mixed at room temperature for 5 minutes, then the temperature was set to 140° C. As the temperature rose, the water was removed from the reaction along with the CPME using the Dean Stark trap. CPME 500 mL was added and washed with DI water twice. The reaction mixture was precipitated by drowning into 2 liters of hexane. The polymer was filtered and dried. The polymer was redissolved in 200 ml tetrahydrofuran (THF), filtered and drowned into 2 liters of hexane, filtered, washed and dried under vacuum at 55° C. Polymer Analysis: GPC weight average molecular weight, Mw, was 3,815, and polydispersity, Pd was 3.01, glass transition temperature, Tg, was 190° C., and elemental analysis, C=89.8%, H=6.60%, N=0.05%, and O=2.6%.

### Example 2

The isothermal thermogravametric analysis, TGA, of the polymer from Exampie 1 was measured at 400° C. for 120 minutes under air using Perkin Elmer TGA 7 and the results showed that the weight loss of the polymer was 1.1%, thus showing that the novel polymer had very minimal weight loss.

### Example 3

7.0 g of the polymer from Example 1 was taken in a bottle, 0.70 g of TMOM-BP was added, 2.80 g of triethylamine salt of dodecylbenzenesulfonic acid at 10% solution in cyclohexanone and 89.5 g of cyclohexanone were added. After shaking over night the formulation was filtered with 0.04 μm filter.

### Example 4

n and k Measurement: The formulation from Example 3 was adjusted to 1.25% solids by weight with cyclohexanone and the mixture was allowed to mix until all the materials become soluble. The homogeneous solution was filtered with 0.2 μm membrane filter. This filtered solution was spin-coated on a 4″ silicon wafer at 2000 rpm. The coated wafer was baked on hotplate at 230° C. for 60 seconds. Then, n and k values were measured with a VASE Ellipsometer manufactured by J. A. Woollam Co. Inc. The optical constants, n and k, of the film for 193 nm radiation were, n=1.54, k=0.37.

### Example 5

The homogeneous solution from Example 3 was filtered with 0.2 μm membrane filter. This filtered solution was spin-coated on a 4″ silicon wafer at 2000 rpm. The coated wafer was baked on hotplate at 230° C. for 60 seconds. After baking, the wafer was cooled to room temp and partially submerged in PGME for 30 seconds. The submerged and unsubmerged parts of the wafer were examined for changes in film thickness. Due to effective cross linking, no film loss was observed.

### Example 6

### Synthesis of Copolymer of 1,3-Adamantane diol and alphamethyl 9-anthracenenmethanol

Example 1 was repeated using alphamethyl 9-anthracenemethanol instead of 9-anthracenemethanol, and the polymer was obtained with the following properties: GPC Mw was 1864, and Pd was 1.78, Tg was 190° C., and elemental analysis, C=90%, H 6.80%, N=0.05%, O=2.27%.

### Example 7

The isothermal thermogravametric analysis, TGA, of the polymer from Example 6 was measured at 400° C. for 120 minutes under air using Perkin Elmer TGA 7 and the results showed that the weight loss of the polymer was 5.57%, thus showing that the novel polymer had very minimal weight loss.

### Example 8

Example 3 was repeated but using the polymer from Example 5.

### Example 9

Example 4 was repeated with example solution from example 8 and n and k values were found to be, n=1.55, k=0.35.

### Example 10

Example 5 was repeated with materials from example 8 and no film loss was observed showing effective crosslinking.

### Example 11

### Synthesis of Copolymer of 1,3-Adamantane diol and Anthracene

Example 1 was repeated using anthracene instead of 9-anthracenemethanol and the polymer obtained had the following properties: GPC Mw=2,166, pd=1.79, H=6.8%, N-0.05%, O=0.8%, C=90.80%

### Example 12

The isothermal thermogravametric analysis, TGA, of the polymer from Example 11 was measured at 400° C. for 120 minutes under air using Perkin Elmer TGA 7 and the results showed that the weight loss of the polymer was 5.9%, thus showing that the novel polymer had very minimal weight loss.

### Example 13

Example 3 was repeated using the polymer from Example 11.

### Example 14

Example 4 was repeated using the solution from example 13 and n and k values were found to be, n-1.55, k=0.35.

### Example 15

Example 5 was repeated with the formulation from example 14 and no film loss was observed.

### Example 16

Blanket etch rates of the antireflective coatings were measured on a NE-5000 N (ULVAC) using both an oxidative and a fluorocarbon-rich etch condition outlined in Table 1. The antireflective coating films of formulations (Example 3 and 8) with about 250 nm thickness were coated on 8 in silicon wafers, baked at 240° C. for 1 minute. Individual film thickness measuring programs on a Nanospec 8000 using Cauchy's material-dependent constants derived by VASE analysis of the films and a 5 point inspection were performed before and after a 20 second etch. Etch rates were then calculated by taking the film thickness difference divided by etch times.

Etch rate masking potential is revealed in the etch rate data in Table 2 and 3 below. Both formulations reveal that they have good etch resistance at 193 nm.

TABLE 1
Etch conditions used in the blanket etch rate studies

| Etch | | |
|---|---|---|
| condition | Oxidative condition | Fluorocarbon condition |
| Gas | Cl₂/O₂/Ar, 24/6/25 SCCM | CF₄/O₂/Ar, 50/20/150 SCCM |
| Process | 1.6 Pa | 5 Pa |
| Pressure | | |

Plate temperature: 20° C.;
RF power: 500 W with 50 W bias.

TABLE 2
Etch rate using Oxidative condition

| Formulation | Etch rate (nm/min) |
|---|---|
| Example 3 | 130.00 |
| Example 8 | 125.00 |

TABLE 3
Etch rate using Fluorocarbon condition

| Formulation | Etch rate (nm/min) |
|---|---|
| Example 3 | 176.00 |
| Example 8 | 185.00 |

### Example 17

Example 1 can be repeated with one equivalent of 1,3-adamanatane diol and two equivalent of a mixture of anthracene, 9-anthracenemethanol, and alphamethl-9-anthracenemethanol to obtain a mixture of co polymers to make spin on carbon hard mask for under layer applications.

1. An absorbing organic spin coatable hard mask antireflective coating composition comprising a crosslinkable polymer, where the crosslinkable polymer comprises at least one aliphatic unit in the backbone of the polymer and at least one substituted or unsubstituted fused aromatic ring in the backbone of the polymer.

2. The composition of claim 1, where the fused aromatic ring has 2 to 10 aromatic rings.

3. The composition of claim 1, where the fused aromatic ring has 2 to 5 aromatic rings.

4. The composition of claim 1I where the fused aromatic ring has 3-4 aromatic rings.

5. The composition of claim 1, where the fused aromatic ring has 3 aromatic rings.

6. The composition of claim 1, where the unit with the fused aromatic ring is selected from

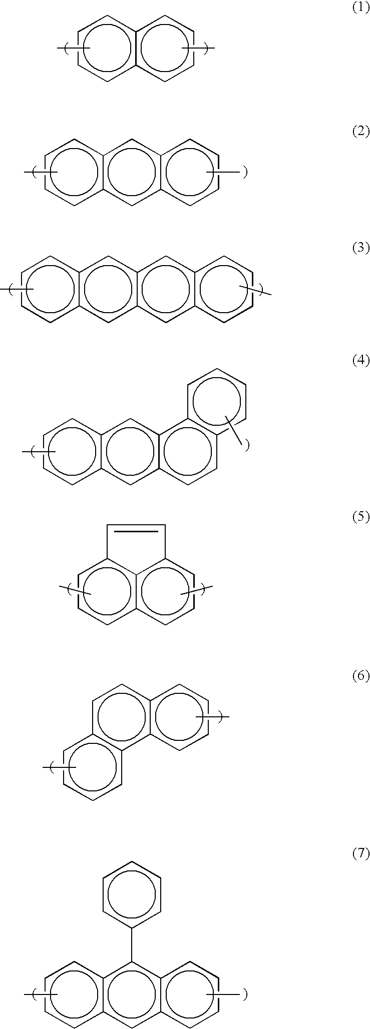

7. The composition of claim 1, where the aliphatic moiety is selected from a cycloalkylene group.

8. The composition of claim 1, where the aliphatic moiety is selected from adamantanylene and perfluoro-adamantylene.

9. The composition of claim 1, where the polymer consists of at least one cycloaliphatic unit and at least one substituted or unsubstituted fused aromatic ring.

10. The composition of claim 1, where the polymer comprises at least one fused ring with 3 aromatic rings and at least one cycloaliphatic ring.

11. The composition of claim 1, where the composition further comprises a crosslinker.

12. The composition of claim 1, where the composition further comprises an acid generator.

13. A process for manufacturing a microelectronic device, comprising,
a) providing a substrate with a first layer of an antireflective coating composition from claim 1;
b) optionally, providing at least a second antireflective coating layer over the first antireflective coating composition layer;
b) coating a photoresist layer above the antireflective coating layers;
c) imagewise exposing the photoresist layer;
d) developing the photoresist layer with an aqueous alkaline developing solution.

14. The process of claim 13, where the first antireflective coating layer has k value in the range of about 0.05 to about 1.0.

15. The process of claim 13, where the second antireflective coating comprises silicon.

16. The process of claim 13, where the second antireflective coating layer has k value in the range of about 0.05 to about 0.5.

17. The process of claim 13, where the photoresist is imageable with radiation from about 240 nm to about 12 nm or nanoimprinting.

18. The process according to claim 13, where the developing solution is an aqueous solution comprising a hydroxide base.

19. A process of making a crosslinkable polymer comprising reacting a monomer comprising a fused aromatic ring moiety with a cyclic aliphatic moiety in the presence of a strong acid.

20. The process of claim 19 comprising reacting in the presence of a strong acid, adamantyl diol or perfluoro 1,3-adamantane diol with at least one of the structures from the group consisting of, 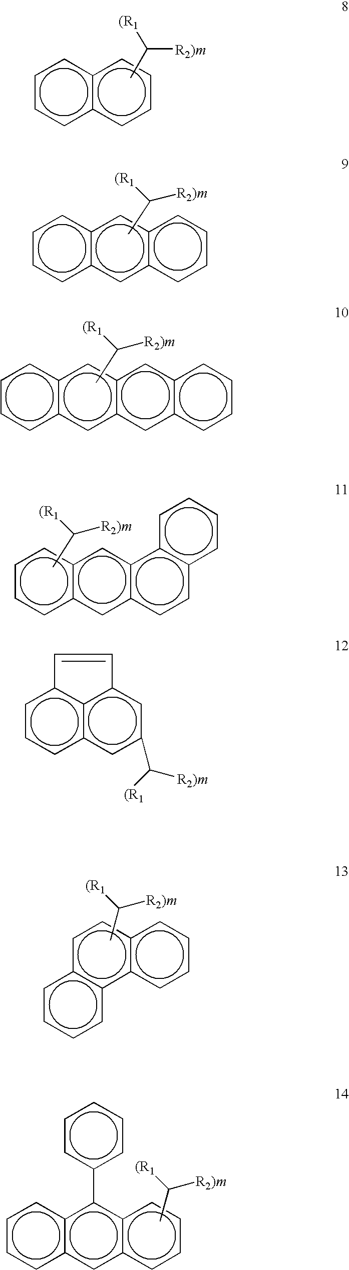
Where, R₁═H, C₁ to C₁₀ alkyl or aryl; R₂═OH, NH₂, alkoxy, and m is one to four.
